(19) United States
(12) Patent Application Publication
(10) Pub. No.: US 2005/0230828 A1
(43) Pub. Date: Oct. 20, 2005

(54) CARRIER, CHIP PACKAGE STRUCTURE, AND CIRCUIT BOARD PACKAGE STRUCTURE

(76) Inventor: Jeng-Da Wu, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,780

(22) Filed: Apr. 15, 2005

(30) Foreign Application Priority Data
Apr. 20, 2004 (TW) 93110946

(51) Int. Cl. H01L 29/40

(52) U.S. Cl. 257/738

(57) ABSTRACT

A chip package structure is provided. The chip package structure has a chip and a carrier, wherein the carrier has a package substrate and a plurality of contacts. The package substrate has a carrying surface and a back surface. The chip is disposed on the carrying surface of the package substrate, and the contacts are disposed on the back surface of the package substrate in a pattern of a plurality of concentric circles. Additionally, the chip package structure can be disposed on a circuit board with solder balls formed on the contacts to form a circuit board package structure. The thermal stress exerted on the solder balls may be uniformly distributed in the carrier, the chip package structure, and the circuit board package structure. The bonding strength between the package substrate and the circuit board is improved.

### CROSS-REFERENCE TO RELATED APPLICATION

This application claims the priority benefit of Taiwan application serial no. 93110946, filed on Apr. 20, 2004. All disclosure of the Taiwan application is incorporated herein by reference.

### BACKGROUND OF THE INVENTION

1. Field of the Invention

The present invention relates to a carrier, a chip package structure, and a circuit board package structure with solder balls arranged in a pattern of a plurality of concentric circles, to evenly distribute thermal stress.

2. Description of the Related Art

In the manufacturing industries of semiconductors, the fabrication of integrated circuits mainly consists of three stages, i.e., firstly, wafer fabrication; secondly, IC fabrication, and thirdly, integrated circuit package. Chips (dies) are fabricated by the processes of forming semiconductor devices on the wafer and then sawing the wafer. Each individual chip that is obtained by sawing the wafer can be electrically connected to external signals via contacts on the chip, and an underfill material is applied to cover the chip for packaging the chip. The objective of the package is to prevent the chip from affecting by external environment such as moisture and noises, etc, and at the same time, provide a medium for electrical connection between the chip and the external circuit. The package procedure of the integrated circuit is thus completed.

In view of high pin count IC devices, because Ball Grid Array (BGA) package provides high pin count and high bonding strength, and requires lower alignment accuracy in bonding, Ball Grid Array package is widely used in the field of chip package. Generally, Ball Grid Array package electrically connects the chip to the substrate via a plurality of wires or bumps by either wire bonding (WB) or flip chip bonding (FC). The package substrate is electrically and structurally connected to a large printed circuit board (PCB) via a plurality of solder balls formed on the contacts so that the two interfaces, two devices or two end points between the package substrate and the printed circuit board achieve signal transmission via the solder balls.

Further, depending on the material of various package substrates, Ball Grid Array package can be categorized as plastic-BGA package (PBGA), ceramic-BGA package (CBGA), and Tape-BGA package (TBGA), which employs tape with conductive patterns being directly adhered with chip.

Referring to FIGS. 1A-1B, FIGS. 1A-1B schematically shows a conventional BGA chip package structure. The chip package structure 100 includes a chip 110, a carrier 120, a plurality of solder balls 130 and a mold compound 140. The carrier 120 comprises a package substrate 122, and a plurality of contacts 124 thereon. The chip 110 is disposed on the carrying surface 122a of the package substrate 122, and is electrically connected to the package substrate 122 by wire bonding. In addition, the contacts 124 are disposed on the back surface 122b of the package substrate 120, and the solder balls 130 are disposed on the contacts 124. The solder balls 130 are electrically connected to the chips 110 via the package substrate 120, serving as a medium for electrical connection between the chip 110 and an external circuit (not shown). Further, the mold compound 140 and the chip 110 are disposed on the same surface of the package substrate 120, and the mold compound 140 covers the chip 110, a portion of the package substrate 120 and a plurality of wires 150 for connecting the chips 110 to the package substrate 120, so as to prevent the chips 110 from influences of external moisture, heat and noises and damage to the wires 150.

As the operating speed of IC devices keeps increasing day by day, the working temperature of the IC devices increases. Due to the fact that the coefficients of thermal expansion (CTE) of the package substrate and the printed circuit board are different, thermal stress is formed correspondingly to the solder balls, under the thermal cycle. Based on the principle of stress distribution and the result of actual observation, the scale of thermal stress exerted onto the solder balls is proportional to the distance between each solder ball and the center of the package substrate, and the thermal stress exerted on to the solder ball, that is relatively far away from the center of the package substrate, is relatively large. However, the conventional solder balls are disposed in an array manner, and under non-uniform thermal stress, the solder balls at the corners of the package substrate shall break first due to excessive thermal stress. As a result, it causes the chip package structure being peeled or the printed circuit board being warped.

### SUMMARY OF THE INVENTION

Accordingly, it is an object of the present invention to provide a chip package structure by changing the arrangement of contacts of the chip package substrate, for increasing the bonding strength between the chip package structure and the external circuit.

Another object of the present invention is to provide a carrier with limited contacts, while the arrangement of the contacts is modified so as to increase the bonding strength between the package substrate and the external circuit board.

A further object of the present invention is to provide a circuit board package structure, wherein the arrangement of the solder balls is changed so as to evenly distribute the thermal stress exerted on the solder balls, which in turn increase the bonding strength between the package substrate and the external circuit board.

In view of the above-mentioned objectives, the present invention provides a carrier suitable for carrying a device. The carrier includes a package substrate and a plurality of contacts. The package substrate, for instance, has a carrying surface and a corresponding back surface. The carrying surface is adapted for carrying devices, and the contacts are disposed on the back surface of the package substrate and are arranged in a pattern of a plurality of concentric circles. The contacts are suitable to be coupled to the devices via the package substrate. Furthermore, the carrier, for instance, is a round carrier, and the device carried by the carrier, for instance, is a chip. The carrier can be used to form a chip package structure of the present invention.

In accordance with a preferred embodiment of the present invention, the center of the concentric circles, for instance, is superimposed with the center of the package substrate, and the distance between a contact and an adjacent contact of the same concentric circle is equal. Further, the carrier or the chip package structure comprises a plurality of solder balls that are correspondingly disposed on the contacts.

The present invention provides a circuit board package structure comprising a circuit board, a chip package element and a plurality of solder balls, wherein the chip package element is disposed on the circuit board. The solder balls are electrically and mechanically connected between the chip package element and the circuit board, and are arranged in a pattern of a plurality of concentric circles.

In the preferred embodiment of the present invention, the chip package element for instance includes a carrier and a chip. The carrier, for instance, has a carrying surface and a corresponding back surface. The chip is disposed on the carrying surface of the carrier, and the chip is electrically connected to the solder balls via the carrier. Further, the center of the concentric circles for instance is superimposed with the center of the chip package element, and the distance between a contact and an adjacent contact of the same concentric circle is equivalent.

The carrier, the chip package structure, and the circuit board package structure of the present invention involve changes of the layout of the carrier such that the arrangement of the contacts of the package substrate is in form of a plurality of concentric circles. The solder balls of each of the concentric circles have equal thermal stress so as to minimize the failure of the solder balls, caused by the intolerance toward excessive thermal stress, and in turn, to increase the bonding strength between the chip package structure and the external circuit board, and to prevent the external circuit board from warp due to thermal stress.

### DESCRIPTION OF THE DRAWINGS

The accompanying drawings are included to provide a further understanding of the invention, and are incorporated in and constitute a part of this specification. The drawings illustrate embodiments of the invention and, together with the description, serve the principles of the invention.

FIGS. 1A and 1B depict a schematic cross-sectional view and a schematic bottom view of a conventional Ball Grid Array chip package structure.

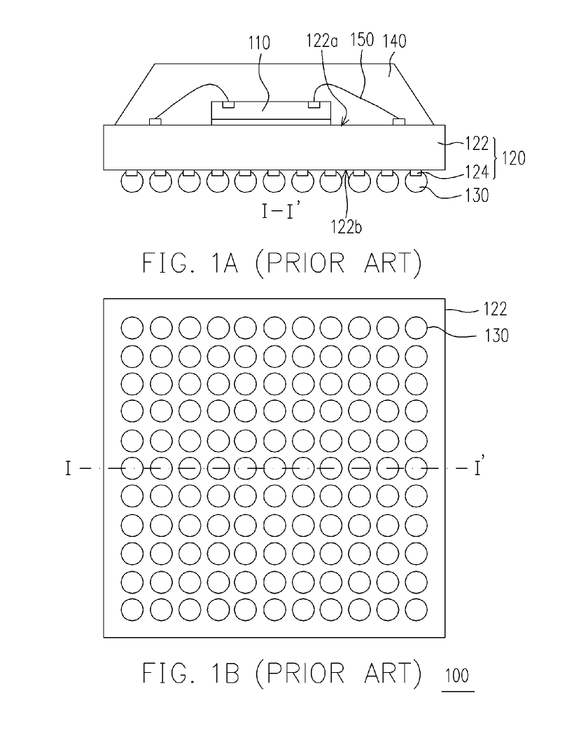

FIGS. 2A and 2B depict a schematic bottom view and a schematic cross-sectional view of a chip package structure in accordance with a preferred embodiment of the present invention.

FIG. 3 is a schematic cross-sectional view of a flip chip package structure in accordance with the preferred embodiment of the present invention.

FIG. 4 is a schematic cross-sectional view of a circuit board package structure in accordance with the preferred embodiment of the present invention.

### DESCRIPTION OF THE PREFERRED EMBODIMENTS

Reference will now be made in detail of the present preferred embodiments of the invention, examples of which are illustrated in the accompanying drawings. Wherever possible, the same reference numbers are used in the drawings and the description to refer to the same or like parts.

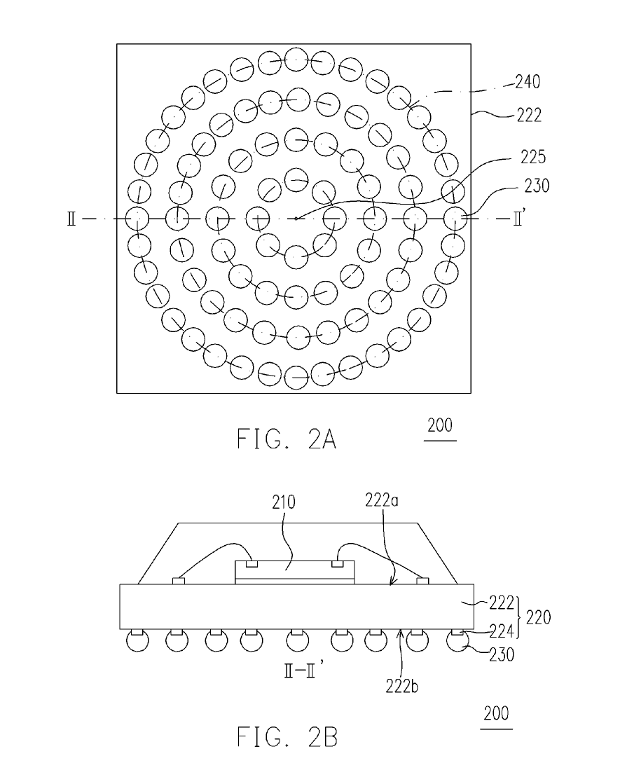

FIGS. 2A to 2B respectively show the schematic bottom and cross-sectional views of a chip package structure according to a preferred embodiment of the present invention. The chip package structure 200, for instance, comprises a chip 210, a carrier 220 and a plurality of solder balls 230, while the carrier 220 has a package substrate 222 and a plurality of contacts 224 thereon. The package substrate 222, for example, can be a plastic substrate, a ceramic substrate or a tape, etc. Further, the contacts 224 are disposed on the back surface 222b of the package substrate 222 and are arranged in a pattern of a plurality of concentric circles 240. The center of concentric circles 240 is the center 226 of the package substrate 222. The each distance between any two adjacent contacts 224 of each concentric circle 240 is equal, and the solder balls 230 are correspondingly disposed on the contacts 224. In other words, the contacts 224 are uniformly, in separation, distributed on the each corresponding concentric circle 240. Further, the chip 210 is disposed on the carrying surface 222a of the package substrate 222 and coupled to the package substrate 222 by, for example, wire bonding, and is electrically and mechanically connected to the solder balls 230 via the package substrate 222.

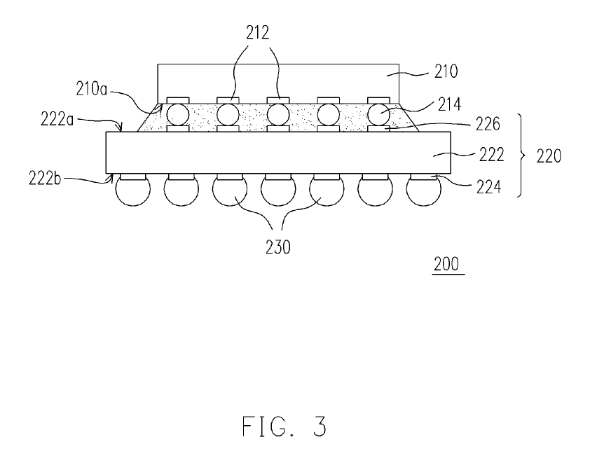

Alternatively, the chip package structure of FIGS. 2A-2B can be a flip chip package structure. Referring to FIG. 3, a schematic cross-sectional view of a flip chip package structure according to another preferred embodiment of the present invention is shown. The chip package structure 200, for instance, comprises a chip 210, a carrier 220 and a plurality of solder balls 230, while the carrier 220 has a package substrate 222 and a plurality of contacts 224, 226 thereon. The package substrate 222, for example, can be a plastic substrate, a ceramic substrate or a tape, etc. Further, the contacts 224 are disposed on the back surface 222b of the package substrate 222 and are arranged in a pattern of a plurality of concentric circles 240. The arrangement of the contacts 224 is similar to the pattern shown in FIG. 2A. The chip 210 includes a plurality of bonding pads 212 on the active surface 210a, while the contacts 226 of the carrier 220 are disposed on the carrying surface 222a of the package substrate 222. The active surface 210a of the chip 210 faces the carrying surface 222a of the package substrate 222 and the chip is electrically coupled to the package substrate 222 by flip chip technology. That is, a plurality of solder bumps 214 electrically and mechanically connect the bonding pads 212 of the chip 210 and the contacts 226 of the carrier 220. The chip 210 is further electrically coupled to the solder balls 230 via the package substrate 222.

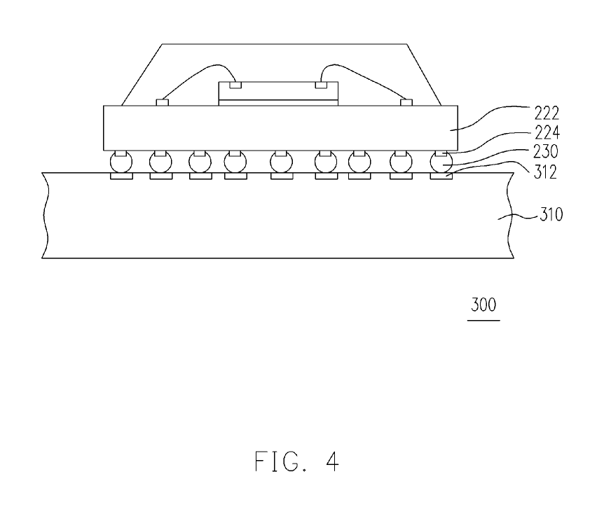

The above chip package structure, for instance, can be disposed on a printed circuit board to form a circuit board package structure. Referring to FIG. 4, a schematic cross-sectional view of a circuit board package structure according to a preferred embodiment of the present invention is shown. The circuit board structure 300 for example comprises the above chip package structure 200 and a printed circuit board 310. The solder balls 230 are disposed between the contacts 224 of the package substrate 222 and the contacts 312 of the printed circuit board 310 so that the chip package structure 200 is electrically and mechanically connected to the printed circuit board 310 by the solder balls 230.

In view of the above description, the present invention modifies the layout of the contacts 224 of the package substrate 222 so that the solder balls 230 are arranged in a pattern of concentric circles 240. Accordingly, due to the fact that the distance between the solder balls 230 on each concentric circle 240 and the center 222a of the package substrate 222 is equal, the thermal stress exerted on the solder balls 230 is evenly distributed, thus avoiding failure of the solder balls 230. It is noted that flip chip bonding or other methods can be employed in coupling the chip to the package substrate. However, the related devices and the methods of disposing thereof are similar to the above preferred embodiments and further description is deemed not necessary.

The contacts, the solder balls and the printed circuit board, etc. described in the embodiments of the present invention are exemplary only and should not be interpreted to limit the present invention. In addition, the shape of the carrier of the present invention is not restricted to the examples, and the shape of the carrier can be circular, oval or rectangular, etc. When each the distance between any two adjacent contacts (or solder balls) on each concentric circle is equal, a better stress distribution is obtained, which provides a better bonding strength. Without affecting the bonding strength of the carrier and the printed circuit board, the distance arrangement of non-equal distances can also be considered. In addition, under the rule of equal distance from each contact of the same concentric circle to the center of the package substrate, the center of the concentric circles is superimposed with the center of the package substrate. In order to, however, accommodate different mode of package substrate and circuit board, and take into consideration of wire design or production costs, the present invention may optimize the position of the center of the concentric circles, the distance between two adjacent concentric circles or the number of solder balls on each concentric circle, together with the adjustment of the distance between the solder balls. Accordingly, an excellent bonding effect is obtained and the yield of package fabrication is improved.

In accordance with the carrier, the chip package structure, and the circuit board package structure of the present invention, the contacts are disposed on the package substrate in the form of concentric circles so that the distance of each contact of the same concentric circle to the center of the package substrate is equal. Accordingly, the thermal stress exerted on the solder balls of each concentric circle is evenly distributed so as to increase the bonding strength between the carrier and the chip package structure with the external circuit board (for instance printed circuit board). This helps avoiding failure of the solder balls and peeling of the chip package structure. Additionally, warp of the circuit board as a result of uneven thermal stress is also prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A chip package structure comprising:
a carrier including a package substrate and a plurality of contacts, wherein the package substrate has a carrying surface and a corresponding back surface and the contacts are disposed on the back surface, and wherein the contacts are arranged in a pattern of a plurality of concentric circles; and
a chip disposed on the carrying surface and coupled to the contacts via the package substrate.

2. The chip package structure of claim 1, wherein a center of the concentric circles is superimposed with a center of the package substrate.

3. The chip package structure of claim 1, wherein the contacts of corresponding each of the concentric circles are in separation uniformly distributed thereon.

4. The chip package structure of claim 1, further comprising a plurality of solder balls correspondingly disposed on the contacts.

5. The chip package structure of claim 1, wherein the carrier is circular.

6. A carrier, adapted for carrying a device, comprising:
a package substrate having a carrying surface and a corresponding back surface, wherein the carrying surface is adapted for carrying the device; and
a plurality of contacts disposed on the back surface, wherein the contacts are arranged into a pattern of a plurality of concentric circles and are coupled to the device via the package substrate.

7. The carrier of claim 6, wherein a center of the concentric circles is superimposed with a center of the package substrate.

8. The carrier of claim 6, wherein the contacts of corresponding each of the concentric circles are in separation uniformly distributed thereon.

9. The carrier of claim 6, further comprising a plurality of solder balls correspondingly disposed on the contacts.

10. The carrier of claim 6, wherein the carrier is circular.

11. A circuit board package structure, comprising:
a circuit board;
a chip package device disposed on the circuit board; and
a plurality of solder balls disposed between and electrically and mechanically connecting the chip package device and the circuit board, and the solder balls being arranged in a pattern of a plurality of concentric circles.

12. The circuit board package structure of claim 11, wherein the chip package device comprises:
a carrier having a carrying surface and a corresponding back surface; and
a chip disposed on the carrying surface of the carrier, and electrically connected to the solder balls via the carrier.

13. The circuit board package structure of claim 12, wherein the solder balls are disposed on the back surface of the carrier.

14. The circuit board package structure of claim 12, wherein the carrier is circular.

15. The circuit board package structure of claim 11, wherein a center of the concentric circles is superimposed with a center of the chip package device.

16. The circuit board package structure of claim 11, wherein the solder balls of corresponding each of the concentric circles are in separation uniformly distributed thereon.

17. A flip chip package structure, comprising:
a carrier including a package substrate and a plurality of contacts, wherein the package substrate has a carrying surface and a corresponding back surface and the contacts are disposed on the back surface, and wherein the contacts are arranged in a pattern of a plurality of concentric circles;
a flip chip electrically coupled to the carrier through a plurality of solder bumps; and
a plurality of solder balls disposed on the contacts of the carrier.

18. The flip chip package structure of claim 17, wherein a center of the concentric circles is superimposed with a center of the package substrate.

19. The flip chip package structure of claim 17, wherein the contacts of corresponding each of the concentric circles are in separation uniformly distributed thereon.

20. The flip chip package structure of claim 17, wherein the carrier is circular.
